(19) United States
(12) Patent Application Publication
(10) Pub. No.: US 2025/0386426 A1
(43) Pub. Date: Dec. 18, 2025

(54) ELECTRONIC CIRCUIT BOARD

(71) Applicant: Hitachi Vantara, Ltd., Yokohama-shi (JP)

(72) Inventors: Masahiro YAO, Tokyo (JP); Norio CHUJO, Tokyo (JP)

(73) Assignee: Hitachi Vantara, Ltd., Yokohama-shi (JP)

(21) Appl. No.: 19/069,046

(22) Filed: Mar. 3, 2025

(30) Foreign Application Priority Data
Jun. 14, 2024 (JP) 2024-096774

(51) Int. Cl. H05K 1/02; H05K 1/11; H05K 1/14

(52) U.S. Cl. CPC H05K 1/0245; H05K 1/0222; H05K 1/0243; H05K 1/0251; H05K 1/115; H05K 1/144; H05K 2201/045; H05K 2201/09481; H05K 2201/09609; H05K 2201/10189; H05K 2201/10704

(57) ABSTRACT

An electronic circuit board includes a plurality of through hole units each having a combination including a pair of signal through holes for differential signals, ground through holes disposed on a straight line connecting the pair of signal through holes, guard through holes, and an anti-pad disposed to surround the pair of signal through holes. The plurality of through hole units are disposed side by side in an X-axis direction and a Y-axis direction while arrangement positions in the X-axis direction are alternately shifted in the Y-axis direction. The guard through holes are disposed on an equidistant straight line positioned at an equal distance from the pair of signal through holes so as to sandwich the pair of signal through holes.

### BACKGROUND OF THE INVENTION

### 1. Field of the Invention

The present invention relates to an electronic circuit board.

### 2. Description of Related Art

Although high-speed communication in an information processing apparatus such as a storage is required, a Nyquist frequency of a signal increases with the high-speed communication, and a loss in a signal transmission path increases. Accordingly, an influence of crosstalk between signals is relatively increased, and there is a problem that signal quality is remarkably degraded as compared with the related art.

The crosstalk in the communication in the information processing apparatus occurs mainly in a connector or a through hole (also referred to as a via hole, but hereinafter referred to as a through hole) of a board included in the signal transmission path. In addition, when a through hole is present near the board on which the connector is mounted, it is necessary to consider crosstalk characteristics of the connector and the through hole in combination, with the larger crosstalk determining the characteristics. Therefore, when the crosstalk occurring in the through hole near the connector is larger than crosstalk of the connector alone, the crosstalk is not reduced even if the connector itself is replaced with a low crosstalk connector, and thus it is required to reduce the crosstalk characteristics of a through hole portion.

When a plurality of through holes are densely disposed in the board, the signal quality is remarkably degraded due to crosstalk noise from adjacent through holes. In order to reduce the crosstalk, it is effective to increase an interval between the through holes, but in a case of a press-fit connector that is generally often used for a connection between a board and a signal line in an information processing apparatus such as a storage, the increase in interval between the through holes increases an interval between pins of the connector, which increases a size of the connector. In addition, when an order of bus interconnects is changed in order to use a lane having a wide pin interval, an area on the board on which components cannot be mounted is increased, and a mounting density of the board is reduced.

As a method for solving the above problem, for example, PTL 1 is known. PTL 1 discloses a method for reducing crosstalk noise between differential signal through holes by disposing a plurality of ground through holes around the signal through hole when signal pins of a connector are mounted in the through holes of a board.

### CITATION LIST

### Patent Literature

PTL 1: JPH03-165473A

### SUMMARY OF THE INVENTION

In the method of PTL 1, since the ground through holes are disposed around the differential signal through holes, an area per pair of differential signal through holes becomes large, and it becomes difficult to dispose the through holes in the board at a high density. In addition, there is a problem that a space for extracting an interconnect from the through hole in the board is small and it is difficult to extract the interconnect.

The invention has been made in view of the above problems, and a main object of the invention is to reduce crosstalk noise while achieving both a high density and ease of interconnect extraction in a through hole of an electronic circuit board.

An electronic circuit board according to the invention includes a plurality of through hole unit each having a combination including a pair of signal through holes for differential signals, a ground through hole disposed on a straight line connecting the pair of signal through holes, at least one guard through hole, and an anti-pad disposed to surround the pair of signal through holes. When an arrangement direction of the pair of signal through holes on a surface of the electronic circuit board is defined as an X-axis direction and a direction perpendicular to the X-axis direction along the surface is defined as a Y-axis direction, the plurality of through hole units are disposed side by side in the X-axis direction and the Y-axis direction while arrangement positions in the X-axis direction are alternately shifted in the Y-axis direction, the ground through hole and the guard through hole are each electrically connected to a ground layer of the electronic circuit board, and the guard through hole includes two first guard through holes disposed on an equidistant straight line positioned at an equal distance from the pair of signal through holes so as to sandwich the pair of signal through holes.

According to the invention, it is possible to reduce crosstalk noise while achieving both a high density and ease of interconnect extraction in a through hole of an electronic circuit board.

### BRIEF DESCRIPTION OF THE DRAWINGS

FIG. 1 is a perspective view showing a configuration example of an information processing apparatus according to the invention;

FIG. 2 is a view showing a schematic structure of a press-fit connector mounted on the information processing apparatus according to the invention and through holes of a board on which the connector is mounted;

FIG. 3 is a view showing a schematic structure of an SMT connector mounted on the information processing apparatus according to the invention and through holes of the board on which the connector is mounted;

FIG. 4 is a view showing a through hole arrangement in a motherboard according to a first embodiment of the invention;

FIG. 5 is a view showing a through hole arrangement in a motherboard according to a second embodiment of the invention;

FIG. 6 is a view showing a through hole arrangement in a motherboard according to a third embodiment of the invention;

FIG. 7 is a view showing a through hole arrangement in a motherboard according to a fourth embodiment of the invention;

FIG. 8 is a view showing a through hole arrangement in a motherboard according to a fifth embodiment of the invention; and

FIG. 9 is a view showing a through hole arrangement in a motherboard according to a sixth embodiment of the invention.

### DESCRIPTION OF EMBODIMENTS

### Configuration of Information Processing Apparatus

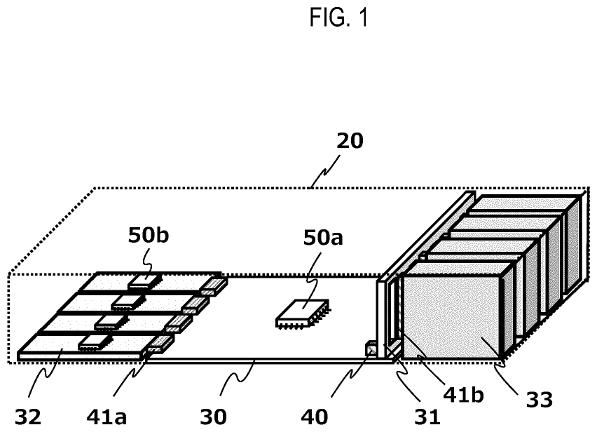

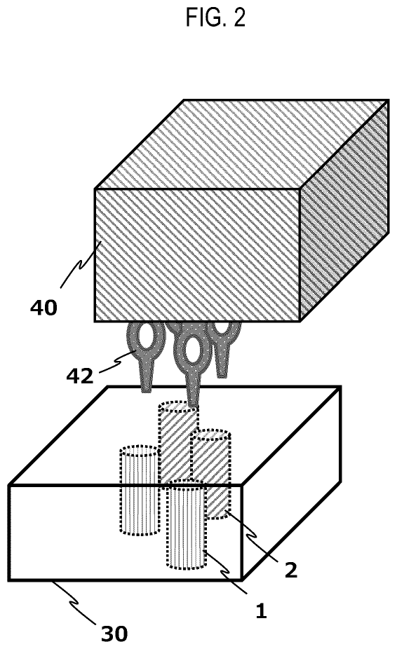

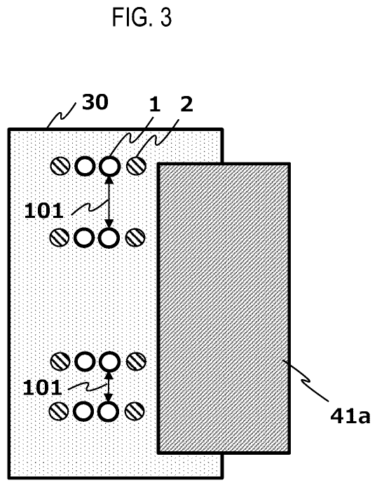

Hereinafter, a configuration of an information processing apparatus including an electronic circuit board according to an embodiment of the invention will be described with reference to FIGS. 1 to 3. FIG. 1 is a perspective view showing a configuration example of the information processing apparatus according to the invention. FIG. 2 is a view showing a schematic structure of a press-fit connector mounted on the information processing apparatus according to the invention and through holes of a board on which the connector is mounted. FIG. 3 is a view showing a schematic structure of a surface mount type (SMT) connector mounted on the information processing apparatus according to the invention and through holes of the board on which the connector is mounted.

An information processing apparatus 20 includes a motherboard 30 as an electronic circuit board, a backplane 31, a plurality of daughter cards 32, and a plurality of drives 33. An IC 50a, a press-fit connector 40, and a plurality of SMT connectors 41a respectively provided corresponding to the plurality of daughter cards 32 are mounted on the motherboard 30.

An IC 50b is mounted on each daughter card 32, and the daughter cards 32 are connected to the motherboard 30 via the SMT connectors 41a. A plurality of SMT connectors 41b respectively provided corresponding to the plurality of drives 33 are mounted on the backplane 31, and the backplane 31 is connected to the motherboard 30 via the press-fit connector 40. The drives 33 are connected to the backplane 31 via the SMT connectors 41b. With these connections, signal transmission is performed among the IC 50a mounted on the motherboard 30, the ICs 50b mounted on the daughter cards 32, and the drives 33.

As shown in FIG. 2, the press-fit connector 40 is provided with a plurality of pins 42 for mounting on the motherboard 30. The pins 42 are inserted into and fixed to signal through holes 1 or ground through holes 2 provided in the motherboard 30. At this time, an interval between the through holes is determined according to a frequency of a signal to be transmitted via the press-fit connector 40.

As shown in FIG. 3, the SMT connector 41a is fixed and connected to a surface layer of the motherboard 30 via solder. In the motherboard 30, the signal through holes 1 and the ground through holes 2 for transmitting signals from the surface layer to an inner layer are provided near the SMT connector 41a. At this time, by making a distance 101 between a pair of signal through holes 1 as short as possible, components and the like can be disposed at a high density on the motherboard 30.

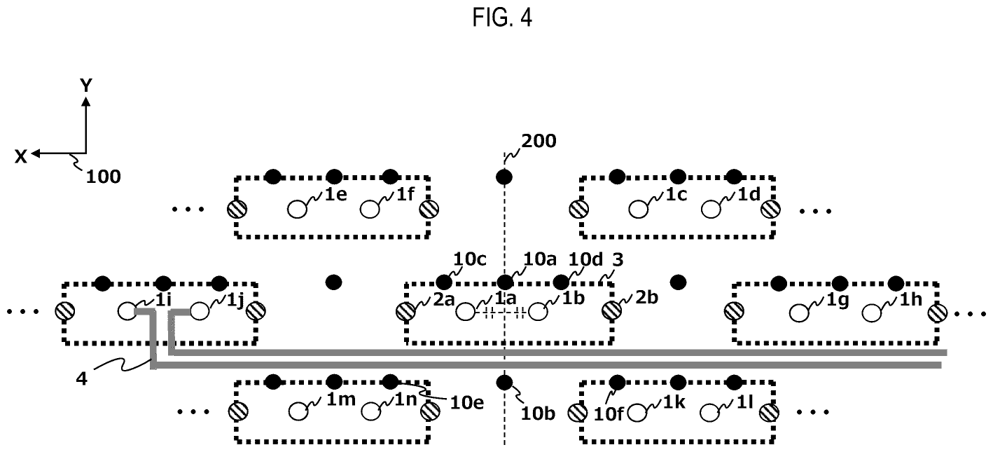

An object of the invention is to reduce crosstalk noise while achieving both a high density and ease of interconnect extraction for the through holes provided in the motherboard 30, for example, the through holes used for mounting the press-fit connector 40 as shown in FIG. 2, and the through holes for transmitting signals to different layers of the motherboard 30 as shown in FIG. 3. Hereinafter, a plurality of embodiments of the invention will be described with reference to FIGS. 4 to 9, each of which shows an example of a through hole arrangement in the motherboard 30 for achieving this object.

### First Embodiment

FIG. 4 is a view showing a through hole arrangement in the motherboard 30 according to a first embodiment of the invention. In FIG. 4, through holes denoted by reference numerals 1a to 1n correspond to the respective signal through holes 1 in FIGS. 2 and 3, and through holes denoted by reference numerals 2a and 2b correspond to the respective ground through holes 2 in FIGS. 2 and 3. Through holes denoted by reference numerals 10a to 10f indicate guard through holes provided for reducing crosstalk noise of the signal through holes 1. Details of these through holes will be described later.

Similarly, through holes not denoted by reference numerals in FIG. 4 correspond to the signal through holes, the ground through holes, or the guard through holes described above. In FIG. 4, the through holes are distinguished from each other according to the type and are shown in a form corresponding to the type. Specifically, each through hole indicated by a white circle represents the signal through hole, each through hole indicated by a black circle represents the ground through hole, and each through hole filled with hatching represents the guard through hole.

In the present embodiment, as shown in FIG. 4, the motherboard 30 is provided with a plurality of pairs of signal through holes each for forming a differential signal. That is, a pair of signal through holes 1a and 1b, a pair of signal through holes 1c and 1d, a pair of signal through holes 1e and 1f, a pair of signal through holes 1g and 1h, a pair of signal through holes 1i and 1j, a pair of signal through holes 1k and 1l, and a pair of signal through holes 1m and 1n are used for transmission of the differential signal. Although not shown in FIG. 4, more pairs of signal through holes may be actually deposed in the motherboard 30.

The pair of signal through holes 1a and 1b for the differential signals is provided with a pair of ground through holes 2a and 2b, four guard through holes 10a to 10d, and an anti-pad 3 provided to surround the signal through holes 1a and 1b. The same applies to other pairs of signal through holes. In the following description, a combination of these through holes provided corresponding to each pair of signal through holes is referred to as a through hole unit. That is, the motherboard 30 according to the present embodiment includes a plurality of through hole units described above, and each through hole unit includes a pair of signal through holes, a pair of ground through holes, four guard through holes, and an anti-pad.

FIG. 4 is a plan view showing an arrangement example of the through holes and the anti-pad on a surface of the motherboard 30. In this plan view, an X-axis direction and a Y-axis direction are defined as indicated by a coordinate axis 100. That is, an arrangement direction of the pair of signal through holes 1a and 1b on the surface of the motherboard 30 is defined as the X-axis direction, and a direction perpendicular to the X-axis direction along the surface of the motherboard 30 is defined as the Y-axis direction.

In the following description, a description of common features of the respective through hole units in the motherboard 30 may be simplified by describing any of the through hole units as a representative example.

The ground through holes 2a and 2b are disposed on a straight line connecting the signal through holes 1a and 1b so as to sandwich the signal through holes 1a and 1b. The ground through holes 2a and 2b are electrically connected to a ground layer (not shown) provided in a part of a plurality of layers constituting the motherboard 30, and form a ground potential of a signal voltage to be applied to the signal through holes 1a and 1b.

The anti-pad 3 provided to surround the signal through holes 1a and 1b is a region obtained by removing a part of a power supply layer and the ground layer for impedance adjustment in the motherboard 30. A shape and size of the anti-pad 3 are appropriately set according to impedances of the signal through holes 1a and 1b due to the differential signals. For example, in FIG. 4, the anti-pad 3 has a rectangular shape, but may have another shape such as an elliptical shape.

Interconnects 4 for signal transmission are extracted from the signal through holes 1i and 1j, respectively. Although FIG. 4 simply shows a state in which the interconnects 4 are extracted only from the signal through holes 1i and 1j, actually, the interconnects for signal transmission are extracted from the pair of signal through holes included in each through hole unit, respectively.

The through hole unit including the signal through holes 1i and 1j and the through hole unit including the signal through holes 1g and 1h are disposed in a +X direction and a −X direction of the through hole unit including the signal through holes 1a and 1b, respectively. An arrangement of the through hole unit including the signal through holes 1e and 1f and the through hole unit including the signal through holes 1c and 1d, and an arrangement of the through hole unit including the signal through holes 1m and 1n and the through hole unit including the signal through holes 1k and 1l are disposed adjacent to the arrangement of the above through hole units in a +Y direction and a −Y direction, respectively. In the arrangement of these through hole units, arrangement positions of the respective through hole units in the X-axis direction are alternately shifted in the Y-axis direction. That is, these through hole units are disposed in the motherboard 30 side by side in the X-axis direction and the Y-axis direction while the arrangement positions in the X-axis direction are alternately shifted in the Y-axis direction.

In the present embodiment, the guard through holes 10a and 10b are disposed on an equidistant straight line 200 positioned at an equal distance from the signal through holes 1a and 1b so as to sandwich the signal through holes 1a and 1b. In addition, the guard through holes 10c and 10d are respectively disposed between the signal through hole 1a and the ground through hole 2a and between the signal through hole 1b and the ground through hole 2b with the equidistant straight line 200 sandwiched therebetween. These guard through holes 10a to 10d are disposed for a purpose of preventing an input of an electric field that causes crosstalk noise from other surrounding signal through holes to the signal through holes 1a and 1b, and are each electrically connected to the ground layer of the motherboard 30. At least a part of the guard through holes 10a, 10c, and 10d is disposed in the anti-pad 3.

In the example of FIG. 4, both the guard through holes 10a and 10b are disposed on the equidistant straight line 200, but positions thereof are not necessarily limited to being on the equidistant straight line 200. As long as the position in the X-axis direction is between the signal through hole 1a and the signal through hole 1b, the arrangement of the guard through holes 10a and 10b is allowed to deviate from the equidistant straight line 200.

The electric fields generated from the respective signal through holes by the differential signals are offset since the electric fields have opposite phases on lines at an equal distance from the pair of through holes forming the differential signals, and are not offset at other positions to form an electric field distribution corresponding to the positions. Here, the electric fields generated from the signal through holes 1f and 1c adjacent to the signal through holes 1a and 1b in the +Y direction interfere with the signal through holes 1a and 1b to generate the crosstalk noise. In the present embodiment, the guard through hole 10c is disposed between the signal through hole 1a and the signal through hole 1f, and the guard through hole 10d is disposed between the signal through hole 1b and the signal through hole 1c. Accordingly, the electric fields applied to the signal through holes 1a and 1b are reduced, and the crosstalk noise can be reduced.

Similarly, the electric fields generated from the signal through holes 1n and 1k adjacent to the signal through holes 1a and 1b in the −Y direction interfere with the signal through holes 1a and 1b to generate the crosstalk noise. In the present embodiment, the guard through hole 10e in the through hole unit including the signal through holes 1m and 1n is disposed between the signal through hole 1a and the signal through hole 1n, and the guard through hole 10f in the through hole unit including the signal through holes 1k and 1l is disposed between the signal through hole 1b and the signal through hole 1k. Accordingly, the electric fields applied to the signal through holes 1a and 1b are reduced, and the crosstalk noise can be reduced.

Further, by disposing the guard through holes 10a and 10b on the equidistant straight line 200 at an equal distance from the signal through holes 1a and 1b, a balance of the differential signals in the signal through holes 1a and 1b can be maintained even when the electric fields generated from other through holes and applied to the signal through holes 1a and 1b cannot be prevented by the guard through holes 10c and 10d or the guard through holes 10e and 10f. For example, when the electric fields applied from the signal through hole 1f to the signal through holes 1a and 1b are considered, a distance from the signal through hole 1f to the signal through hole 1a is different from a distance from the signal through hole 1f to the signal through hole 1b, and thus magnitudes of these electric fields are different from each other. In this way, when the electric fields having different magnitudes are applied to the pair of signal through holes 1a and 1b that transmit the differential signals, the balance of the differential signals is lost, and an influence of the crosstalk noise increases. In the present embodiment, in order to prevent this, the guard through hole 10a is disposed between the signal through holes 1a and 1b and the signal through hole 1f on the equidistant straight line 200 at an equal distance from the signal through holes 1a and 1b, so that the magnitude of the electric fields applied to the signal through holes 1a and 1b are not biased, and the balance of the differential signals in the signal through holes 1a and 1b is maintained. Therefore, the crosstalk noise can be greatly reduced. In particular, since the guard through holes 10a and 10b are respectively disposed on both sides in the +Y direction and the −Y direction with respect to the pair of signal through holes 1a and 1b, it is possible to effectively reduce the crosstalk noise due to an electric field from another adjacent signal through hole on both sides in the +Y direction and the −Y direction.

In addition, the guard through holes 10a, 10c, and 10d are disposed side by side on one side in the Y-axis direction with respect to the signal through holes 1a and 1b. Therefore, the interconnect 4 can be linearly extracted from the other side where the guard through holes 10a, 10c, and 10d are not disposed, and the interconnect 4 can be easily extracted.

Similarly, the guard through holes are disposed with respect to other signal through holes in the same arrangement as the guard through holes 10a to 10d in each through hole unit. Accordingly, it is possible to facilitate the extraction of the interconnect 4 while reducing the crosstalk noise in all of the signal through holes.

In addition to the guard through holes 10a to 10d, guard through holes may be further added. For example, in addition to the guard through holes 10a, 10c, and 10d disposed side by side in the X-axis direction, the number of guard through holes may be increased on the same line.

According to the first embodiment of the invention described above, the following effects are obtained.

(1) The motherboard 30 as an electronic circuit board includes a plurality of through hole units each having a combination including a pair of signal through holes 1a and 1b for differential signals, ground through holes 2a and 2b disposed on a straight line connecting the pair of signal through holes 1a and 1b, at least one of guard through holes 10a to 10d, and the anti-pad 3 disposed to surround the pair of signal through holes 1a and 1b. When an arrangement direction of the pair of signal through holes 1a and 1b on a surface of the motherboard 30 is defined as an X-axis direction and a direction perpendicular to an X-axis direction along the surface of the motherboard 30 is defined as a Y-axis direction, the plurality of through hole units are disposed side by side in the X-axis direction and the Y-axis direction while arrangement positions in the X-axis direction are alternately shifted in the Y-axis direction. The ground through holes 2a and 2b and the guard through holes 10a to 10d are each electrically connected to a ground layer of the motherboard 30. In such a through hole arrangement in the motherboard 30, the guard through hole includes two guard through holes 10a and 10b (first guard through holes) disposed so as to sandwich the pair of signal through holes 1a and 1b on the equidistant straight line 200 positioned at an equal distance from the pair of signal through holes 1a and 1b. In this manner, it is possible to reduce crosstalk noise in the through hole arrangement in the motherboard 30.

(2) The guard through hole further includes two guard through holes 10c and 10d (second guard through holes) disposed in the anti-pad 3 across the equidistant straight line 200. In this manner, electric fields applied to the signal through holes 1a and 1b from other signal through holes adjacent in the Y-axis direction can be reduced, and the crosstalk noise can be further reduced.

(3) One of the two guard through holes 10a and 10b (guard through hole 10a) and the two guard through holes 10c and 10d are linearly disposed side by side along the X-axis direction. In this manner, an interconnect 4 extending from the pair of signal through holes 1a and 1b can be linearly extracted from an opposite side without passing through a board region where these guard through holes are disposed side by side. Therefore, in addition to the reduction of the crosstalk noise, it is possible to achieve both a high density and ease of extraction of the interconnect 4.

### Second Embodiment

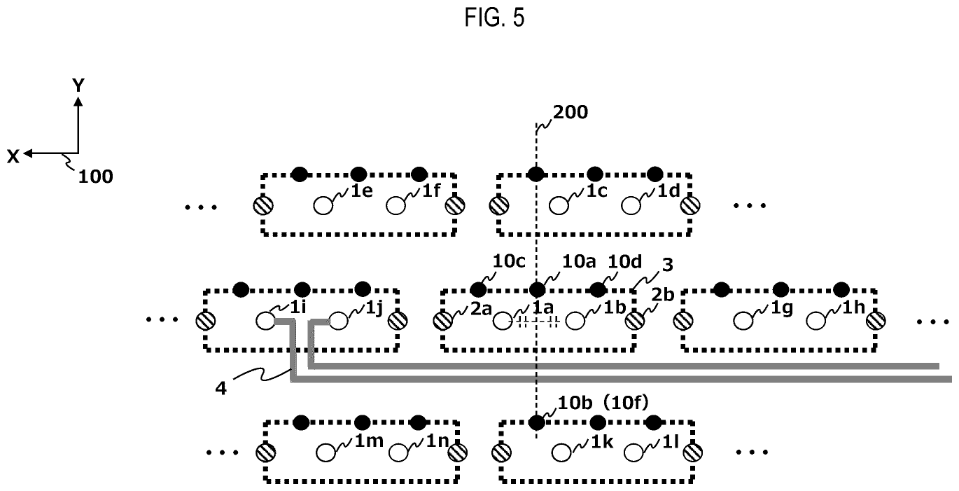

FIG. 5 is a view showing a through hole arrangement in the motherboard 30 according to a second embodiment of the invention. Hereinafter, the through hole arrangement according to the present embodiment will be described focusing on differences from those in the first embodiment described with reference to FIG. 4.

In the present embodiment, in the through hole unit including the pair of signal through holes 1a and 1b, the guard through hole 10b of the guard through holes 10a and 10b described in the first embodiment is shared with the guard through hole 10f of the through hole unit adjacent to the through hole unit in the −Y direction, that is, the through hole unit including the signal through holes 1k and 1l. The same applies to other through hole units. Accordingly, the same through hole arrangement as that described in the first embodiment is implemented while reducing the number of guard through holes in the entire motherboard 30.

In the present embodiment, as in the first embodiment, a guard through hole may be further added, or the arrangement of the guard through holes may be shifted.

According to the second embodiment of the invention described above, when any through hole unit (through hole unit including the signal through holes 1a and 1b) of the plurality of through hole units is defined as a first through hole unit and the through hole unit (through hole unit including the signal through holes 1k and 1l) adjacent to the first through hole unit along the Y-axis direction is defined as a second through hole unit, the guard through hole 10b in the first through hole unit and the guard through hole 10f in the second through hole unit are shared. In this manner, it is possible to reduce the number of guard through holes in the entire motherboard 30 while implementing the same through hole arrangement as that described in the first embodiment. As a result, it is possible to further achieve a high density of the through hole arrangement.

### Third Embodiment

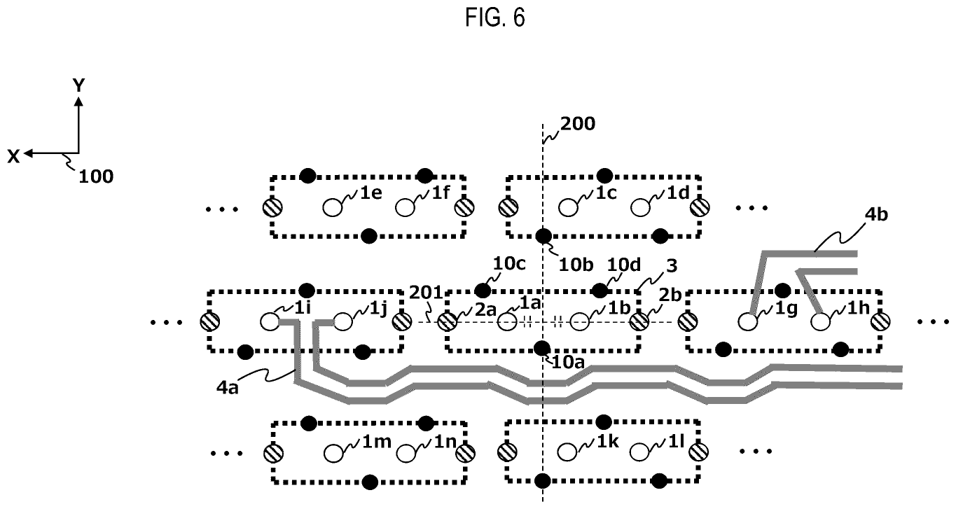

FIG. 6 is a view showing a through hole arrangement in the motherboard 30 according to a third embodiment of the invention. Hereinafter, the through hole arrangement according to the present embodiment will be described focusing on differences from those in the second embodiment described with reference to FIG. 5.

In the present embodiment, with respect to a straight line 201 connecting the pair of signal through holes 1a and 1b, the guard through hole 10a is disposed on one side (−Y direction side) in the Y-axis direction, and the guard through holes 10c and 10d are disposed on the other side (+Y direction side). At this time, the guard through hole 10b is shared with the guard through hole of any one of the through hole units (in FIG. 6, the through hole unit including the signal through holes 1c and 1d) adjacent in the Y-axis direction. Further, in the respective through hole units adjacent to the through hole unit including the signal through holes 1a and 1b in the X-axis direction and the Y-axis direction, that is, the through hole unit including the signal through holes 1c and 1d, the through hole unit including the signal through holes 1g and 1h, the through hole unit including the signal through holes 1i and 1j, and the through hole unit including the signal through holes 1k and 1l, the guard through holes are disposed such that the positions of the guard through holes corresponding to the guard through holes 10a to 10d in these through hole units are inverted. Accordingly, it is possible to easily extract an interconnect for differential signal transmission from each signal through hole in the −Y direction or the +Y direction, for example, as in interconnects 4a and 4b, while implementing reduction of crosstalk noise by the through hole arrangement similar to that described in the first embodiment for each signal through hole. Therefore, layers of the extracted interconnects from the respective signal through holes disposed side by side in the X-axis direction can be formed in the same layer in the motherboard 30. A clearance (not shown), which is a region for avoiding contact with the interconnect, is provided around each guard through hole, and the interconnects 4a and 4b have an interconnect pattern for avoiding this. In the present embodiment, since the guard through holes are disposed at a sufficient interval in each through hole unit, the interconnects 4a and 4b can be selectively extracted from the signal through holes in the −Y direction or the +Y direction without coming into contact with the clearance of the guard through holes.

In the present embodiment, as in the first and second embodiments, a guard through hole may be further added, or the arrangement of the guard through holes may be shifted.

According to the third embodiment of the invention described above, in a plurality of through hole units, the guard through hole 10a (first guard through hole) is disposed on one side, and the guard through holes 10c and 10d (second guard through holes) are disposed on the other side in the Y-axis direction with respect to the straight line 201 connecting the pair of signal through holes 1a and 1b. In this manner, it is possible to improve ease of interconnect extraction while implementing reduction of crosstalk noise in the same manner as described in the first and second embodiments.

When a through hole unit (the through hole unit including the signal through holes 1i and 1j or the through hole unit including the signal through holes 1g and 1h) adjacent to the first through hole unit (the through hole unit including the signal through holes 1a and 1b) along the X-axis direction is defined as a third through hole unit, the guard through holes are disposed in the plurality of through hole units such that the positions of the guard through holes in the second through hole unit and the third through hole unit are inverted with respect to the positions of the guard through holes 10a and 10b and the guard through holes 10c and 10d in the first through hole unit. In this manner, it is possible to disperse a direction of the interconnect extracted from each signal through hole, and as a result, a degree of freedom in designing the layer of the extracted interconnect in the motherboard 30 is increased.

### Fourth Embodiment

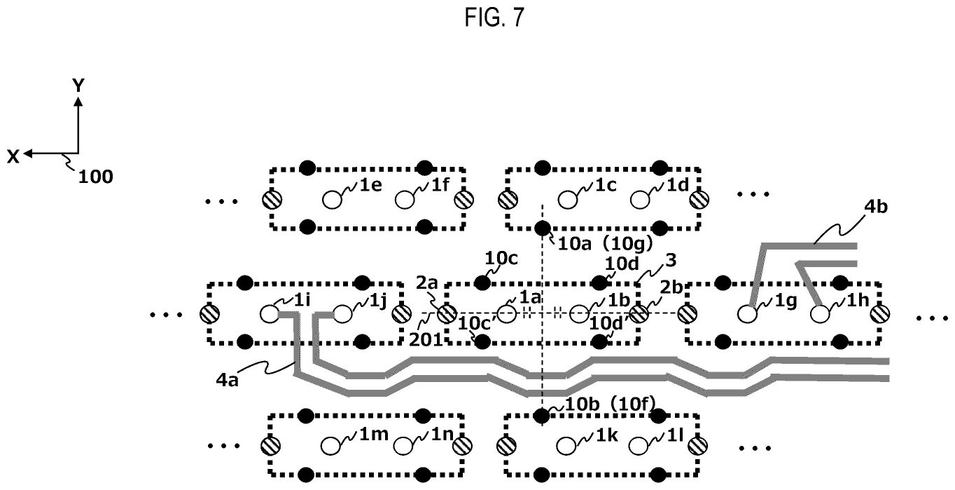

FIG. 7 is a view showing a through hole arrangement in the motherboard 30 according to a fourth embodiment of the invention. Hereinafter, the through hole arrangement according to the present embodiment will be described focusing on differences from those in the third embodiment described with reference to FIG. 6.

In the present embodiment, with respect to the straight line 201 connecting the pair of signal through holes 1a and 1b, the two guard through holes 10c and 10d and two guard through holes 10c′ and 10d′ are disposed on one side (+Y direction side) and the other side (−Y direction side) in the Y-axis direction, respectively. Similar to the guard through holes 10c and 10d, the guard through holes 10c′ and 10d′ are for reducing crosstalk noise due to an electric field generated from the signal through hole adjacent to the signal through holes 1a and 1b in the −Y direction. The guard through holes 10a and 10b are shared with the guard through holes of the through hole units adjacent in the +Y direction and the −Y direction (the through hole unit including the signal through holes 1c and 1d and the through hole unit including the signal through holes 1k and 1l). Accordingly, the same through hole arrangement and effects as those of the third embodiment can be implemented. That is, while reducing the crosstalk noise, interconnects, for example, the interconnects 4a and 4b, in the −Y direction or the +Y direction can be easily extracted from the respective signal through holes, and it is possible to implement the through hole arrangement in which layers of the extracted interconnects from the respective signal through holes disposed side by side in the X-axis direction can be formed in the same layer in the motherboard 30.

In the present embodiment, as in the first to third embodiments, a guard through hole may be further added, or the arrangement of the guard through holes may be shifted.

According to the fourth embodiment of the invention described above, in a plurality of through hole units, the two guard through holes 10c and 10d (second guard through holes) and the two guard through holes 10c′ and 10d′ (second guard through holes) are disposed on one side and the other side in the Y-axis direction with respect to the straight line 201 connecting the pair of signal through holes 1a and 1b. In this manner, it is possible to improve ease of interconnect extraction while implementing the same through hole arrangement in the same manner as described in the first and second embodiments. Further, in both of the interconnects 4a and 4b extracted from the signal through holes 1i and 1j and the signal through holes 1g and 1h in the −Y direction and the +Y direction, respectively, the guard through hole can be prevented from being disposed between these interconnects. Therefore, the interconnects 4a and 4b can be extracted without impairing the interconnect impedance.

### Fifth Embodiment

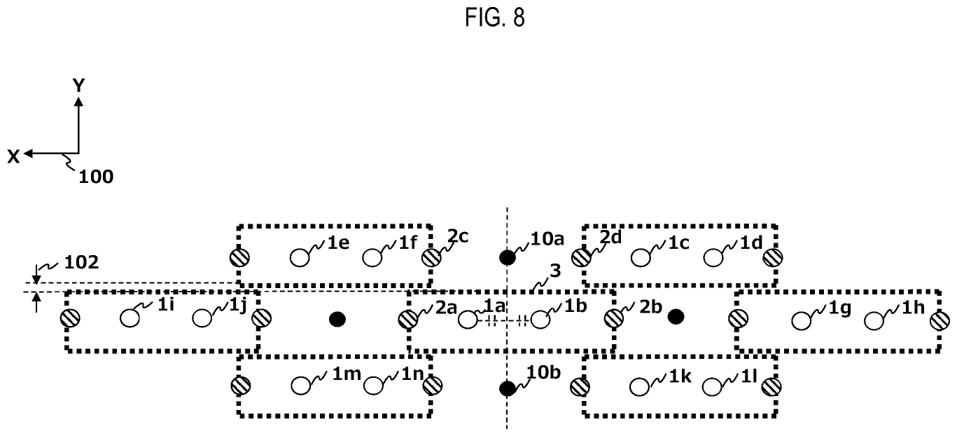

FIG. 8 is a view showing a through hole arrangement in the motherboard 30 according to a fifth embodiment of the invention. Hereinafter, the through hole arrangement according to the present embodiment will be described focusing on differences from those in the first embodiment described with reference to FIG. 4.

In the present embodiment, only the two guard through holes 10a and 10b are disposed around the through hole unit including the pair of signal through holes 1a and 1b so as to sandwich the signal through holes 1a and 1b. These guard through holes 10a and 10b are shared with guard through holes of other through hole units adjacent in the +Y direction and the −Y direction, respectively. Accordingly, even when a distance 102 between the anti-pad 3 of the through hole unit including the signal through holes 1a and 1b and an anti-pad of another through hole unit adjacent in the Y-axis direction is short, and the guard through hole cannot be disposed here, the same through hole arrangement and effects as those of the first embodiment can be implemented. In addition, the number of guard through holes in the entire motherboard 30 can be reduced to further achieve a high density of the through hole arrangement, and the interconnect can be extracted from each signal through hole without impairing an interconnect impedance.

In the present embodiment as well, as in the first to fourth embodiments, the arrangement of the guard through holes may be shifted.

According to the fifth embodiment of the invention described above, similar to each of the first to fourth embodiments, in the through hole arrangement in the motherboard 30, it is possible to achieve both a high density due to reduction of crosstalk noise and ease of interconnect extraction.

### Sixth Embodiment

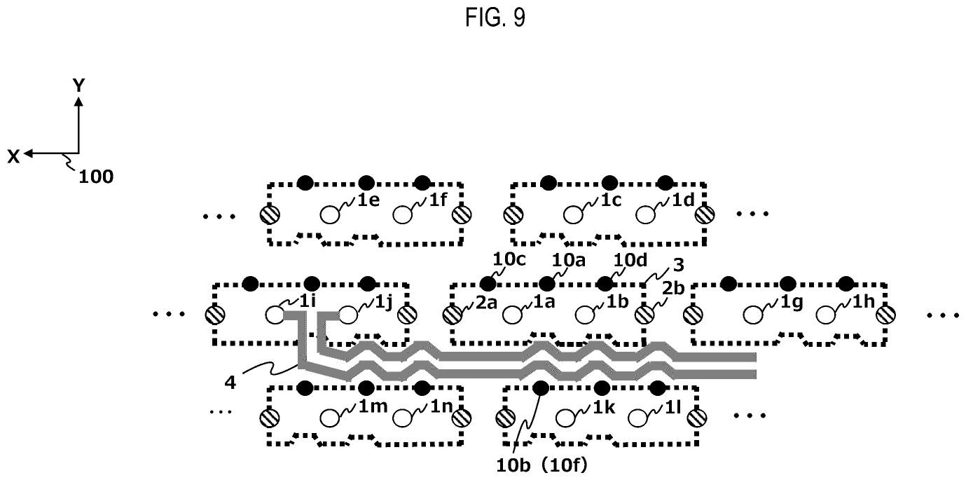

FIG. 9 is a view showing a through hole arrangement in the motherboard 30 according to a sixth embodiment of the invention. Hereinafter, the through hole arrangement according to the present embodiment will be described focusing on differences from those in the second embodiment described with reference to FIG. 5.

In the present embodiment, an anti-pad of each through hole unit has a shape recessed in the Y-axis direction. Accordingly, since the interconnect 4 can be routed to the recessed portion of the anti-pad, it is possible to provide an interconnect allowable region in the motherboard 30 in a wider range than that in the second embodiment. As a result, impedance design of the interconnect 4 can be facilitated. The anti-pad may have a shape recessed in the X-axis direction instead of being recessed in the Y-axis direction.

According to the sixth embodiment of the invention described above, the anti-pad of each through hole unit has a shape recessed in the X-axis direction or the Y-axis direction. In this manner, it is possible to increase the interconnect allowable region of the motherboard 30 and facilitate the impedance design of the interconnect 4.

The invention is not limited to the above-described embodiments, and other forms conceivable within the scope of the technical idea of the invention are also included in the scope of the invention as long as the features of the invention are not impaired. In addition, the above-described embodiments and a plurality of modifications may be combined.

What is claimed is:

1. An electronic circuit board comprising:
a plurality of through hole units each having a combination including a pair of signal through holes for differential signals, a ground through hole disposed on a straight line connecting the pair of signal through holes, at least one guard through hole, and an anti-pad disposed to surround the pair of signal through holes, wherein
when an arrangement direction of the pair of signal through holes on a surface of the electronic circuit board is defined as an X-axis direction and a direction perpendicular to the X-axis direction along the surface is defined as a Y-axis direction, the plurality of through hole units are disposed side by side in the X-axis direction and the Y-axis direction while arrangement positions in the X-axis direction are alternately shifted in the Y-axis direction,
the ground through hole and the guard through hole are each electrically connected to a ground layer of the electronic circuit board, and
the guard through hole includes two first guard through holes disposed on an equidistant straight line positioned at an equal distance from the pair of signal through holes so as to sandwich the pair of signal through holes.

2. The electronic circuit board according to claim 1, wherein
the guard through hole further includes two second guard through holes disposed in the anti-pad across the equidistant straight line.

3. The electronic circuit board according to claim 2, wherein
one of the two first guard through holes and the two second guard through holes are linearly disposed side by side along the X-axis direction.

4. The electronic circuit board according to claim 2, wherein
when any through hole unit of the plurality of through hole units is defined as a first through hole unit and the through hole unit adjacent to the first through hole unit along the Y-axis direction is defined as a second through hole unit, the first guard through hole in the first through hole unit and the second guard through hole in the second through hole unit are shared.

5. The electronic circuit board according to claim 4, wherein
in the plurality of through hole units, the first guard through hole is disposed on one side and the second guard through hole is disposed on the other side in the Y-axis direction with respect to a straight line connecting the pair of signal through holes.

6. The electronic circuit board according to claim 5, wherein
when the through hole unit adjacent to the first through hole unit along the X-axis direction is defined as a third through hole unit, the first guard through hole and the second guard through hole are respectively disposed in the plurality of through hole units such that positions of the first guard through hole and the second guard through hole in the second and third through hole units are inverted with respect to positions of the first guard through hole and the second guard through hole in the first through hole unit.

7. The electronic circuit board according to claim 4, wherein
in the plurality of through hole units, two second guard through holes are respectively disposed on one side and the other side in the Y-axis direction with respect to a straight line connecting the pair of signal through holes.

8. The electronic circuit board according to claim 1, wherein
the anti-pad has a shape recessed in the X-axis direction or the Y-axis direction.
